(19) United States
(12) Patent Application Publication
(10) Pub. No.: US 2013/0033804 A1
(43) Pub. Date: Feb. 7, 2013

(54) SPRING MODULE AND SLIDE TYPE PORTABLE TERMINAL INCLUDING THE SAME

(71) Applicants: Sung-Gwan WOO, Gyeonggi-do (KR); Chung-Keun YOO, Gyeonggi-do (KR); Hyun-Suk SHIN, Gyeonggi-do (KR)

(72) Inventors: Sung-Gwan WOO, Gyeonggi-do (KR); Chung-Keun YOO, Gyeonggi-do (KR); Hyun-Suk SHIN, Gyeonggi-do (KR)

(73) Assignee: Samsung Electronics Co., LTD., Gyeonggi-do (KR)

(21) Appl. No.: 13/545,096

(22) Filed: Jul. 10, 2012

(30) Foreign Application Priority Data
Aug. 3, 2011 (KR) 10-2011-0077285

(51) Int. Cl. F16F 3/02; H05K 5/00

(52) U.S. Cl. 361/679.01; 267/165

(57) ABSTRACT

A spring module includes: a resilient member having a pair of wire parts extending side by side along an axial direction and a connecting part connecting the wire parts at ends of the wire parts; and fastening members provided at opposite ends of the resilient member, respectively, wherein the resilient member provides a resilient force, which is applied in a direction which is inclined from the axial direction if the fastening members are positioned so as to be inclined away the axial direction, the resilient member being deformed as the fastening members move closer to or further away from each other.

### CLAIM OF PRIORITY

This application claims the priority of the earlier filing date, under 35 U.S.C. §119(a), of an application entitled “Spring Module and Slide Type Portable Terminal Including the Same” filed in the Korean Intellectual Property Office on Aug. 3, 2011 and assigned Serial No. 10-2011-0077285, the contents of which are hereby incorporated by reference.

### BACKGROUND OF THE INVENTION

1. Field of the Invention

The present invention relates to a resilient driving body, and more particularly to a spring module adapted to provide a driving force for moving a pair of housings in a slide type portable terminal, where the housings are slidably coupled to each other to face each other.

2. Description of the Related Art

In general, a portable terminal refers to a device which provides a user with a communication function, a game function, a multimedia function, an electronic note function, etc. while the user is carrying it. In recent years, mobile communication terminals are equipped with a game function, a multimedia function, and an electronic note function. Moreover, development of the mobile communication technology enables an internet only function through a mobile communication terminal

Portable terminals are classified into a bar type, a folder type, and a slide type according to their appearances. In the case of a folder type or slide type portable terminal, an input unit such as a keypad and an output unit such as a display may be distributed in a pair of housings, and the housings may overlap each other while the portable terminal is carried. Thus, folder type or slide type portable terminals which can be conveniently carried have occupied a considerable part of the portable terminal market.

Additionally, as a multimedia function is reinforced among the functions of a portable terminal, displays are increasing. In order to secure the portability of such a portable terminal while increasing the functionality of the displays, it is inevitably necessary to reduce a thickness of a portable terminal in order to maintain its small size and light weight. In the case of a folder type portable terminal, since housings are pivotally coupled to each other using a hinge unit at the ends of the housings, the coupling structure of the housings rarely influences the thickness of the portable terminal Meanwhile, since a pair of housings face each other when they are slid with respect to each other in a slide type portable terminal, the coupling structure of the housings significantly influences the thickness of the portable terminal Moreover, when a resilient driving body such as a spring module is disposed between the housings of such a slide type portable terminal, the thickness of the portable terminal cannot help but be increased when the thickness of the spring module is increased.

Accordingly, many efforts have been continuously made for the small size and light weight of the slide type portable terminal, i.e. for reduction of the thickness of a spring module disposed between housings of a slide type portable terminal As a whole, a spring module provides a driving force applied in a direction along which a portable terminal is opened or closed according to movement sections of housings while pivoting between the housings. Many such spring modules and installation structures of the spring modules are disclosed in U.S. Pat. No. 7,967,346 (registered on Jun. 28, 2011) etc.

A spring module of a slide type portable terminal needs to be stably disposed between housings, have a thin thickness, and provide a sufficient driving force required to move the housings. However, there is a limit in configuring a spring module which provides a sufficient driving force while having a thin thickness. Moreover, when the spring module disposed between the housings fails to maintain a posture substantially parallel to the housings while the housings are slid, a part of the spring module may interfere with the housings, damaging the housings. Moreover, if the thickness of the spring module is reduced, the spring module may be distorted or deformed in an unsuitable direction, increasing a possibility of damaging the housings due to interferences.

Accordingly, in a slide type portable terminal, there is a demand for a spring module having a reduced thickness which can provide a sufficient driving force, while at the same time have an increased structural stability so as to prevent damage to the housings.

### SUMMARY OF THE INVENTION

Accordingly, an aspect of the present invention is to solve the above-mentioned problems occurring in the prior art and by providing a spring module having a structure which allows for easily reducing the thickness thereof, contributing to reduction of a thickness of a slide type portable terminal

Another aspect of the present invention is to provide a spring module for a slide type portable terminal which can achieve a sufficient driving force while reducing the thickness thereof

Yet another aspect of the present invention is to provide a slide type portable terminal which can prevent a spring module from interfering with housings during the sliding movement of the housings due to its stable structure.

In accordance with an aspect of the present invention, there is provided a spring module including: at least one resilient member having a pair of wire parts extending side by side along an axial direction, and a connecting part connecting the wire parts at ends of the wire parts; and fastening members provided at opposite ends of the resilient member, respectively, wherein the resilient member provides a resilient force, which is applied in a direction which is inclined from the axial direction if the fastening members are positioned so as to be inclined from the axial direction, the resilient member being deformed as the fastening members move closer to or further away from each other.

At least a pair of resilient members may be disposed such that one of the wire parts of one of the resilient members is disposed between the wire parts of the other resilient member.

In accordance with another aspect of the present invention, there is provided a slide type portable terminal where a pair of housings are coupled to each other to be slid with respect to each other and face each other, the slide type portable terminal including: a spring module including: at least one resilient member having a pair of wire parts extending side by side and a connecting part connecting the wire parts at ends of the wire parts; and fastening members accommodating ends of the wire parts at one end of the resilient member and accommodating the connecting part at an opposite end of the resilient member, wherein one of the fastening members is supported by a first housing of the housings and the other fastening member is supported by a second housing of the housings, and wherein a resilient force is provided in a direction along which the fastening members are positionable away from each other as the housings are slid with respect to each other.

Other aspects, advantages and salient features of the invention will become apparent to those skilled in the art from the following detailed description, which, taken in conjunction with the annexed drawings, discloses exemplary embodiments of the invention.

### BRIEF DESCRIPTION OF THE DRAWINGS

The above and other aspects, features and advantages of the present invention will be more apparent from the following detailed description taken in conjunction with the accompanying drawings, in which:

FIG. 1 is is an exploded perspective view illustrating a spring module of a slide type portable terminal according to an exemplary embodiment of the present invention.

FIG. 2 is a plan view illustrating resilient members of the spring module of FIG. 1;

FIG. 3 is a plan view illustrating the resilient members of the spring module of FIG. 2, which are coupled to each other;

FIG. 4 is a perspective view illustrating a first fastening member among fastening members of the spring module of FIG. 1;

FIG. 5 is a perspective view illustrating a coupled state of the spring module of FIG. 1;

FIG. 6 is a plan view for explaining an operation of the spring module of FIG. 1;

FIG. 7 is a perspective view illustrating a slide type portable terminal including the spring module of FIG. 1; and

FIG. 8 is a perspective view for explaining an operation of the spring module in the portable terminal of FIG. 7.

### DETAILED DESCRIPTION

The following description with reference to the accompanying drawings is provided to assist in a comprehensive understanding of exemplary embodiments of the invention as defined by the claims and their equivalents. It includes various specific details to assist in that understanding but these are to be regarded as merely exemplary. Accordingly, those of ordinary skill in the art will recognize that various changes and modifications of the embodiments described herein can be made without departing from the scope and spirit of the invention. Also, descriptions of well-known functions and constructions are omitted for clarity and conciseness.

Throughout the drawings, like reference numerals will be understood to refer to like parts, components and structures.

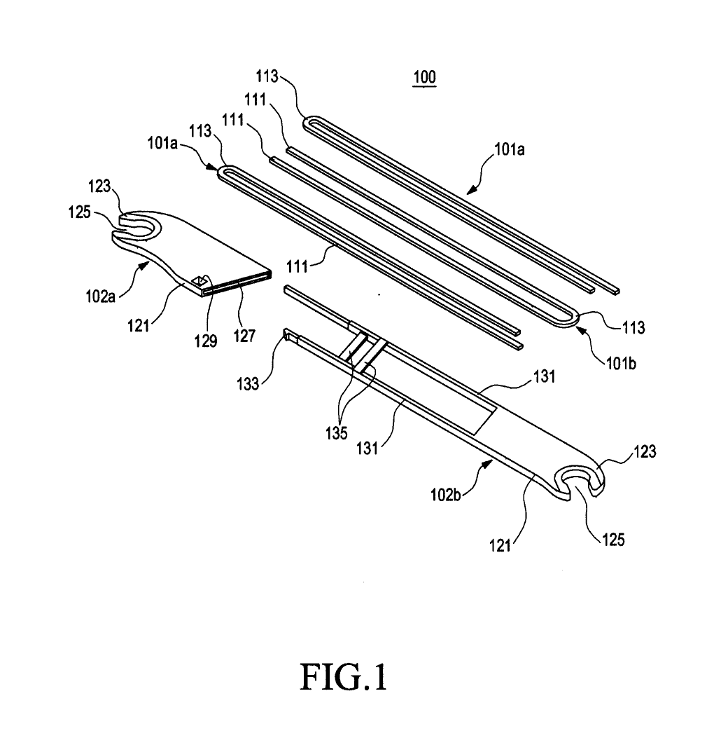

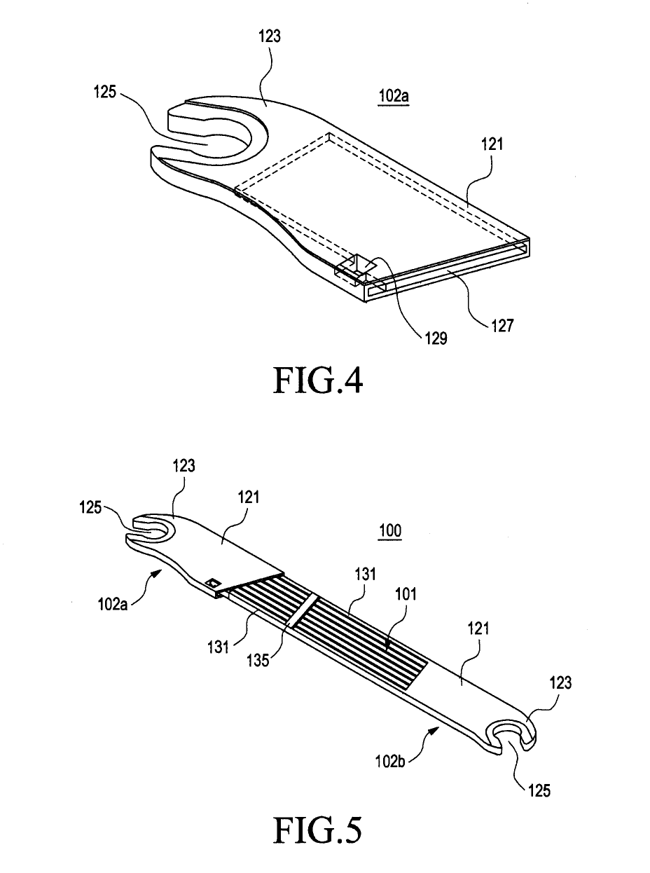

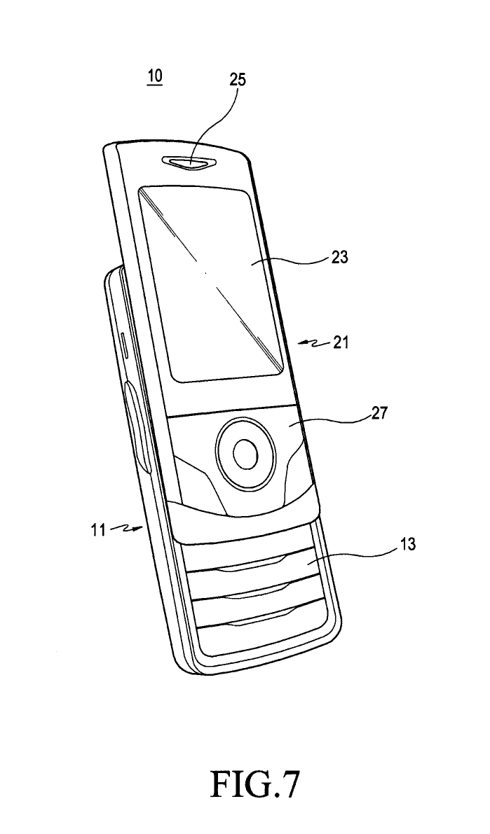

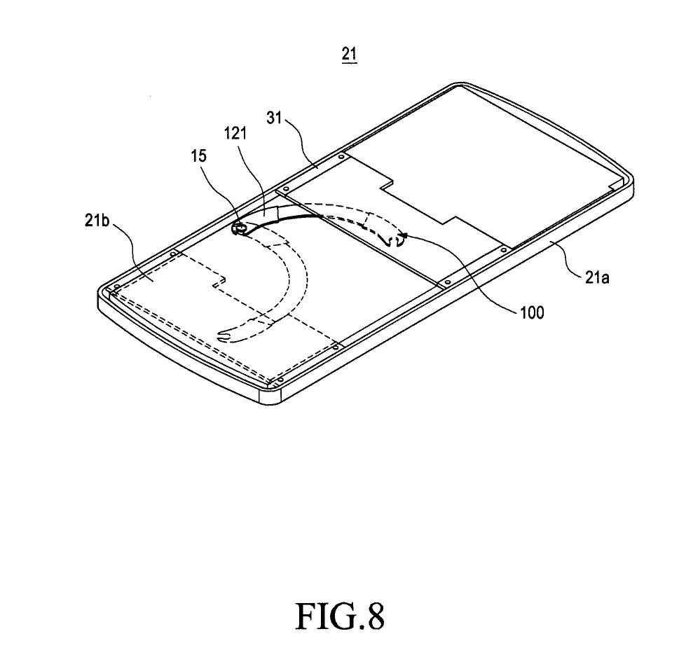

Referring to FIGS. 1 to 5, a spring module 100 according to an embodiment of the present invention has a structure where fastening members 102a and 102b are disposed at opposite ends of a U-shaped resilient member 101. The spring module 100 is installed in a portable terminal 10 (see FIGS. 7 and 8) where a pair of housings 11 and 21 (see FIG. 7) are slidably coupled to each other in an opposed manner so as to face each other, and provides a driving force while the housings 11 and 21 (see FIG. 7) are slid with respect to each other. More specifically, the spring module 100 is installed such that one end thereof is supported by one of the housings 11 or 12 and an opposite end thereof is supported by the other housing 11 or 12, spring module 100 providing a resilient force which is applied in a direction along which the opposite ends of the spring module 100 move away from each other when housings 11 and 21 are slid with respect to each other.

The resilient member 101 includes a pair of wire parts 111 and a connecting part 113 connecting the wire parts 111. The wire parts 111 extend side by side, more preferably, in parallel to each other, and the connecting part 113 connects one end of each of the wire parts 111 to each other. Because the wire parts 111 are connected to each other at their respective ends using the connecting part 113, the resilient member 101 is relatively easily deformable in a direction parallel to an imaginary plane where the wire parts are located, but is relatively more difficult to deform in other directions. If a plurality of such resilient members 101 were disposed side by side, the spring module 100 would be relatively easy to deform in a direction parallel to an imaginary plane where the wire parts 111 are located but be substantially restrained from being easily deformed in other directions.

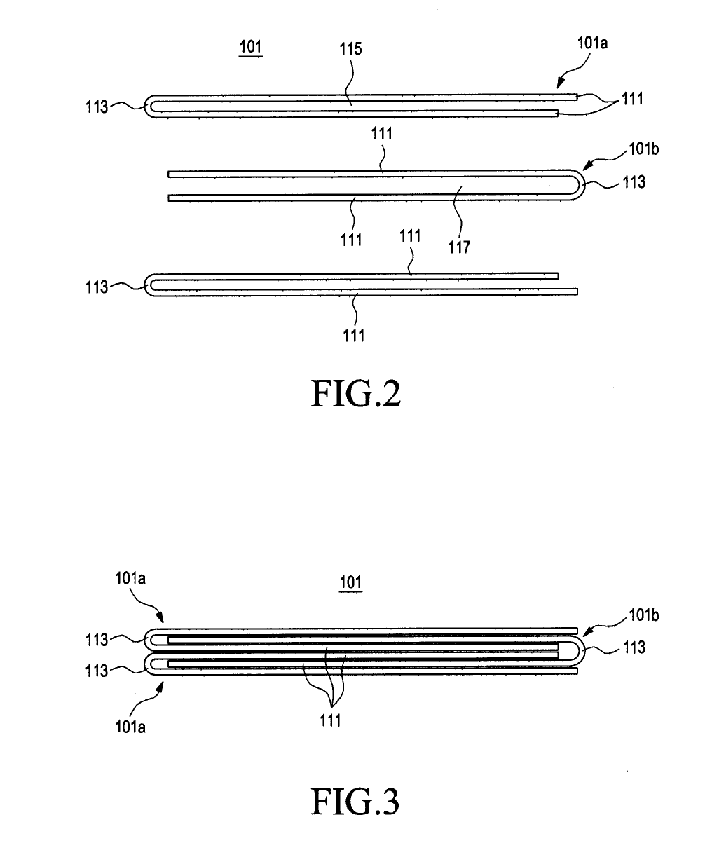

FIGS. 2 and 3 illustrate a detailed structure where the resilient members 101 are disposed in accordance with one embodiment of the invention. For simplicity, a pair of resilient members 101a each having a connecting part at the left side thereof among the resilient members 101 shown in FIGS. 2 and 3 are referred to as “first resilient members” 101a, and a resilient member 101b having a connecting part at the right side thereof is referred to as ‘a second resilient member 101b. In the spring module 100 according to the exemplary embodiment of the present invention, the three resilient members are disposed alternately, and at least one of the wire parts of each resilient member 101a and 101b are disposed between the wire parts of the other resilient members 101a and 101b. However, in an embodiment where the spring module 100 may include only a pair of resilient members, one of the wire parts of one resilient member may be disposed between the wire parts of the other resilient member. In further embodiments of the invention, the spring module 100 may include more than three resilient members. In this case, at least one of the wire parts of each resilient member may also be disposed between the wire parts of other resilient members.

Referring again to FIGS. 2 and 3, the pair of first resilient members 101a are disposed in parallel, and the second resilient member 101b is also disposed in parallel, but between the first resilient members 101a. Then, the connecting part 113 of each first resilient member 101a is disposed at one side, e.g. at the left side thereof, and the connecting part of the second resilient member 101b is disposed at an opposite side, e.g. at the right side thereof Then, as mentioned above, at least one of the wire parts 111 of each resilient member 101a and 101b is located between the wire parts of the other resilient members 101a and 101b.

More specifically, one of the wire parts of each first resilient member 101a is disposed in a space 117 between the wire parts of the second resilient member 101b, resulting in two wire parts of the first resilient members 101a being disposed between the wire parts of the second resilient member 101b. The other one of the wire parts of each first resilient member 101a surrounds the second resilient member 101b on the outer side of the second resilient member 101b such that, each wire part of the second resilient member 101b is is disposed in a space 115 located between the wire parts of a respective one of the first resilient members 101a.

Although in the resilient members 101a and 101b, the lengths of the wire parts 111 or the intervals 115 and 117 between the wires 111 may be different, the pairs of the wire parts 111 are disposed in parallel and one end of a wire part 111 is connected to one end of the counterpart wire part 111 using the connecting part 113 so that they form a U-like shape. The wire parts 111 of each resilient member 101a and 101b are disposed side by side on one plane. Assuming that the plan views of FIGS. 1 and 3 are illustrated on an XY plane in a Cartesian coordinate system, the resilient members 101a and 101b are relatively easily deformable on the XY plane or a plane parallel to the XY plane in a curved fashion to accumulate a resilient force. Thus, although the resilient members 101a and 101b are deformable in a curved fashion, they are relatively difficult to deform, that is, restrained from being deformed, in any plane that is not parallel to the XY plane, thereby providing the spring module 100 with a resilient coupling structure that is stable in three dimensions.

The spring module 100 includes the fastening members 102a and 102b so that it may be fastened with the housings 11 and 12 of the slide type portable terminal in a manner so that the coupling state of the resilient members 101a and 101b is maintained. One of the fastening members 102a and 102b is fastened with the first housing 11 and the other one of the fastening members 102a and 102b is fastened with the second housing 21. Accordingly, the spring module 100 is disposed between the housings 11 and 21 with the opposite ends thereof being supported by one of the housings 11 and 21, so as to provide a resilient force which is applied to push the opposite ends thereof away from each other. When the housings 11 and 21 are slid with respect to each other, the spring module 100 is deformed such that the opposite ends thereof get closer to each other (thereby increasing the amount of applied resilient force) or away from each other (thereby decreasing the amount of applied resilient force). A structure where such a spring module 100 is disposed between housings 11 and 21 of the portable terminal 10 to provide a driving force can be easily understood by those skilled in the art via the portable terminal shown in U.S. Pat. No. 7,967,346 (issued on Jun. 28, 2011).

As shown in FIG. 1, the fastening members 102a and 102b are adapted to receive the connecting parts 113 or wire parts 111 of the resilient members 101a and 101b. For convenience' sake, a fastening member accommodating the connecting parts of the first resilient members 101a and the ends of the wire parts of the second resilient member 102a are referred to as a first fastening member' 102a and a fastening member accommodating the connecting part of the second fastening member 101b and the ends of the wire parts of the first resilient members 101a are referred to as ‘a second fastening member’ 102b. Accordingly, the fastening members 102a and 102b accommodate the ends of the wire parts 111 at one end of the resilient members 101a and 101b and accommodate the connecting parts 113 at an opposite end of the resilient members 101a and 101b.

Each of the first and second fastening members 102a and 102b includes an accommodating part 121 for accommodating ends of the resilient members 101a and 101b, and a fastening part 123 integrally formed with the accommodating part 121 which is fastened with and supported by one of the housings 11 and 21.

The accommodating parts 121 are adapted to accommodate the connecting parts 113 or ends of the wire parts 111 of the resilient members 101a and 101b and maintain the coupled position of the resilient members 101a and 101b. Additionally, each of the accommodating parts 121 includes an accommodating hole 127 extending from one end of the corresponding fastening member 102a and 102b which is in a direction that is opposed to the end including the fastening part 123. One of the opposite ends of each resilient member 101a and 101b is accommodated within the accommodating hole 127 of one of the fastening members 102a and 102b. A coupling recess 129 is formed on one side of the accommodating hole of the first fastening member 102a. A coupling hook 133 formed in a guide member 131, which will be described later, is adapted to be coupled to the coupling recess 129. The accommodating part 121, i.e. the accommodating hole 127 is configured to extend along a direction in which the resilient members 101a and 101b extend. The fastening part 123 extends from one end of the accommodating part 121, and may extend in a direction which is inclined from the direction in which the resilient members 101a and 101b extend. A pivoting hole 125 extends from a portion of the periphery of the fastening part 123 is formed in a respective one of the fastening parts 123. The pivoting holes 125 are engaged with a pivoting member 15 (see FIG. 8) formed in each of the housings 11 and 21 of the portable terminal 10 (only pivoting member 15 of housing 11 being shown in FIG. 8) so that both ends of the spring module 100 can be pivotally mounted to the housings 11 and 21 of the portable terminal 10. Alternatively, only one of the pivoting holes 125 are engaged with a pivoting member 15 of the portable terminal 10, so that only one end of the spring module 100 can be pivotally mounted to one of housings 11 and 21 of the portable terminal 10.

In the above-described configuration the first and second fastening members 102a and 102b are similar in that an accommodating part 121 and a fastening part 123 are each located in a respective one of . However, the first and second fastening members 102a and 102b are different in that the coupling recess 129 is formed in the first fastening member 102a and the above-mentioned guide members 131 are formed in the second fastening member 102b. The coupling hook 133 formed in the guide member 131 is coupled to the coupling recess 129 in order to connect the first and second fastening members 102a and 102b together.

The guide members 131 extend in parallel from opposite sides of the accommodating hole 127 (not shown) of the second fastening member 102b. The coupling hook 133 is formed at one end of the guide members 131 and the remaining guide member 131 extends longer than the guide member 131 having the coupling hook 133 which will be accommodated within the accommodating hole 127 of the first fastening member 102a.

In order to assemble the spring module 100, the ends of the resilient 30 members 101a and 101b are accommodated within the accommodating hole 127 of the first fastening member 102a and the opposite ends thereof are accommodated within the accommodating hole 127 of the second fastening member 102b. The guide members 131 are located to surround the wire parts 111 disposed on the outermost side of the resilient members 101a and 101b. Next, the coupling hook 133 is coupled to the coupling recess 129 to maintain a connected state between the first and second coupling members 102a and 102b, and the guide member, which does not include the coupling hook 133 but is longer than the guide member 131 that does include the coupling hook 133, is accommodated within the accommodating hole 127 to finish assembly of the spring module 100.

Meanwhile, in order to more effectively restrain the resilient members 101a and 101b exposed between the first and second fastening members 102a and 102b from deviating from a certain plane, e.g. the above-mentioned XY plane, the spring module 100 may further include support members 135. The support members 135 are located between the first and second fastening members 102a and 102b and positioned so as to connect the guide members 131 one to the other. One of the support members 135 is disposed on one of the opposed surfaces formed by the above-described interleaved/nested arrangement of the resilient members 101a and 101b, and the other one of the support members 135 is disposed on the opposed surface formed by the arrangement of the resilient members 101a and 101b, so that the support members 135 face each other. That is, the resilient members 101a and 101b are disposed between the support members 135. Accordingly, the opposite ends of the resilient members 101a and 101b are constrained by the fastening members 102a and 102b, and the opposite side ends and the opposed surfaces formed by the arrangement of the resilient members 101a and 101b are surrounded by the combination of the guide members 131 and the support members 135.

When the portable terminal 10 is assembled, the spring module 100 remains almost linear. In other words, when the spring module 100 is assembled in the portable terminal 10, the housings 11 and 21 of the portable terminal 10 are slid with respect to each other from a closed position where they overlap to a completely opened position. Then, the spring module 100 accumulates a minimum resilient force in a range within which the housings 11 and 21 of the portable terminal 10 are moved. That is, since the spring module 100 provides a resilient force by which the opposite ends thereof are away from each other, it accumulates a minimum resilient force when it is linear. Meanwhile, since the spring module 100 may provide a resilient force even in a closed state where the housings 11 and 21 of the slide type terminal 10 overlap each other or even in a completely opened state in a range within which the housings 11 and 21 can move, the closed or opened state of the housings 11 and 21 may be stably maintained.

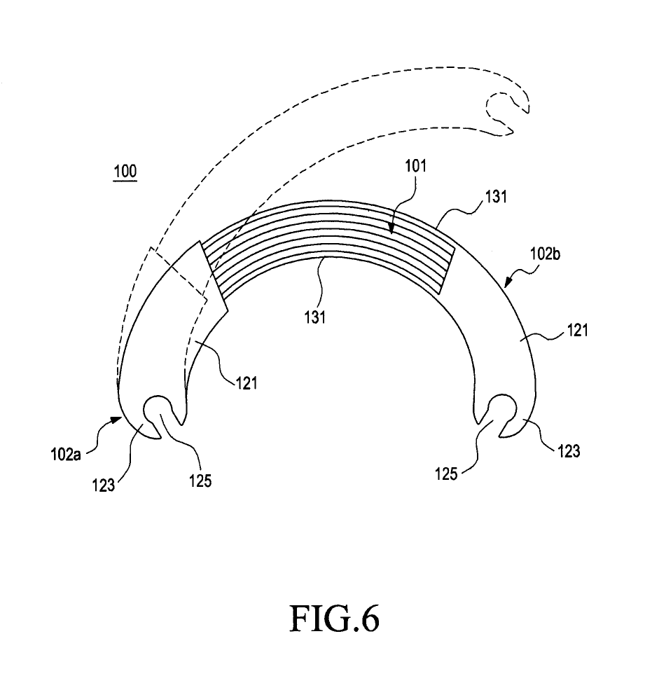

Meanwhile, if the housings 11 and 21 of the portable terminal 10 to which the spring module 100 is coupled are slid with respect to each other, the spring module 100 is pivoted with respect to the housings 11 and 21 so that the opposite ends thereof get close to or away from each other. Thus, the spring module 100 accumulates a resilient force while being deformed to a certain shape. A modified example of the spring module 100 according to movement of the housings 11 and 21 is illustrated in FIG. 6. As mentioned above, the spring module 100 is deformed only on a plane where the resilient members 101a and 101b are disposed, e.g. on an XY plane in the Cartesian coordinate system, and is restrained from being deformed in another direction even while the housings 11 and 21 are moving. This operation is achieved by the shapes of the resilient members 101a and 101b, i.e. the fastening members 102a and 102b, the guide members 131, and the support members 135.

Accordingly, since the spring module 100 is deformed on a plane parallel with and between the housings 11 and 21 of the slide type portable terminal 10, the possibility of damaging the housings 11 and 21 due to interferences is reduced. Further, since the number of the resilient members 101a and 101b can be increased or decreased as desired so as to provide a resilient force needed for a particular design (thereby increasing or decreasing the amount of resilient force provided by the spring module 100), a sufficient resilient force required to open and close the portable terminal 10 can be provided without requiring a change in the thicknesses of the resilient members 101a and 101b. This is particularly important when various types of portable terminals 10 having different spatial and force requirements are contemplated, so that a single type of spring module 10, having a constant, relatively thin thickness, can be designed for meeting many different force requirements. Thus, a spring force change between the different spring modules can be accomplished by changing the number of resilient members 101a and 101b included therein, and not by a change in the thickness of the resilient members 101a and 101b, which change in thickness may be incompatible with the different types of portable terminals 10.

FIG. 7 illustrates a slide type portable terminal 10 where the spring module is installed, and FIG. 8 illustrates the portable terminal 10 where the first housing 11 of FIG. 7 is show removed. The portable terminal 10 includes the first housing 11 having a keypad 13 on one surface thereof, and the second housing 21 having a display unit 23. The second housing 21 is slidably coupled to the first housing 11 so as to allow opening and close the keypad 13. Moreover, the second housing 21 may include a second keypad 27 having various function keys for movement of a menu item, starting/ending of a voice communication, and loading of a menu item, and a receiver 25 is disposed at an upper end of the second housing 21.

In order to couple the second housing 21 to the first housing 11, the portable terminal 10 includes a guide member 31. The guide member 31 is fixedly mounted to the first housing 11, is located on the upper side of the keypad 13, and is slidably coupled to the second housing 21. Irrespective of the sliding movement of the second housing 21, the guide member 31 is normally hidden from the view of the use by the second housing 21.

One end of the spring module 100 is supported by the first housing 11, and an opposite end thereof is supported by the second housing 21. Pivoting bosses 15 are formed in the first and second housings 11 and 12 to support the spring module 100. Since the guide member 31 is mounted to the first housing 11, the pivot boss 15 formed in the first housing 11 is preferably formed in the guide member 31. The pivoting boss 15 formed in the second housing 21 is formed on a rear surface of the second housing 21.

As the pivoting holes 125 of the fastening members 102a and 102b are pivotally coupled to one of the pivoting bosses 15, the opposite ends of the spring module 100 are pivotally installed in the first and second housings 11 and 21 while being supported by the first and second housings 11 and 21 respectively.

In the state of FIG. 8, the keypad 13 of the portable terminal 10 remains hidden, and is opened when the second housing 21 is slid upwards to the point where the guide member 31 is located at the position indicated by a dotted line 21b. While the keypad 13 is moving between the hidden point and the opened point, the opposite ends of the spring module 100 get closer to or farther away from each other. Accordingly, the resilient force accumulated when the opposite ends of the spring module 100 get closer to each other moves the second housing 21 in a direction along which the keypad 13 is opened or closed.

According to the present invention, since the spring module having the above-mentioned configuration includes a U-shaped resilient member, the resilient member can be restrained from being twisted, resulting in a stable structure. Moreover, when a plurality of resilient members are alternately disposed to accommodate portions of other resilient members, the entire spring module can be effectively restrained from being twisted. Thus, the spring module becomes structurally stable, preventing it from interfering with the housings while the housings are slid with respect to each other. Furthermore, if it were desired to reduce the thickness of the spring module 100 by reducing the thicknesses of the resilient members themselves, an increased plurality of resilient members can be used to form a spring module so as to retain the same resilient force as if increased thickness resilient members were used. This makes it possible to provide a sufficient driving force necessary for moving the housings of the slide type portable terminal while contributing to a reduction of the thicknesses of the resilient members, and as well as, the thickness of the spring module, and thus, the thickness of the slide type portable terminal 10.

While the invention has been shown and described with reference to a certain embodiment thereof, it will be understood by those skilled in the art that various changes in form and details may be made therein without departing from the spirit and scope of the invention as defined by the appended claims, some of such changes already being noted in the above description.

What is claimed is:

1. A spring module comprising:
at least one resilient member having a pair of wire parts extending side by side along an axial direction, and a connecting part connecting the wire parts at ends of the wire parts; and
fastening members provided at opposite ends of the resilient member, respectively,
wherein the resilient member provides a resilient force, which is applied in a direction which is inclined from the axial direction if the fastening members are positioned so as to be inclined from the axial direction, the resilient member being deformed as the fastening members move closer to or further away from each other.

2. The spring module as claimed in claim 1, wherein at least a pair of resilient members are disposed such that one of the wire parts of one of the resilient members is disposed between the wire parts of the other resilient member.

3. The spring module as claimed in claim 1, wherein three resilient members are disposed in parallel with each other such that connecting parts of a pair of first resilient members of the resilient members are coupled to a first fastening member of the fastening members, and a connecting part of a second resilient member of the resilient members is coupled to a second fastening member of the fastening members.

4. The spring module as claimed in claim 3, wherein one of the wire parts of each of the first resilient members is disposed between the wire parts of the second resilient member.

5. The spring module as claimed in claim 3, wherein one of the wire parts of the second resilient member are disposed between the wire parts of the first resilient members, respectively.

6. The spring module as claimed in claim 3, wherein one of the wire parts of each of the first resilient members is disposed to surround one of opposite side surfaces of the second resilient member.

7. The spring module as claimed in claim 1, wherein the wire parts of the resilient member extend parallel to each other.

8. The spring module as claimed in claim 1, wherein each of the fastening members includes an accommodating part for accommodating one end of the resilient member and a fastening part integrally formed with the accommodating part.

9. The spring module as claimed in claim 1, further comprising:
a coupling recess formed in a first fastening member of the fastening members;
a pair of guide members formed in a second fastening member of the fastening members; and
a coupling hook formed in one of the guide members and coupled to the coupling recess,
wherein the guide members surround side surfaces of the resilient member, respectively.

10. The spring module as claimed in claim 9, further comprising at least a pair of support members coupling the guide members respectively, wherein the support members are disposed between the fastening members to face one of opposite surfaces of the resilient member, respectively.

11. The spring module as claimed in claim 9, wherein each of the fastening member includes an accommodating part for accommodating one end of the resilient member and a fastening part integrally formed with the accommodating part, and wherein the guide members are accommodated adjacent to peripheries of the first fastening member, respectively.

12. The spring module as claimed in claim 11, wherein the coupling recess is formed on one side of the accommodating part.

13. The spring module as claimed in claim 9, wherein the guide members are disposed on a plane where the wire parts are disposed.

14. The spring module as claimed in claim 8, further comprising a pivoting hole formed in the fastening part.

15. A slide type portable terminal where a pair of housings are coupled to each other, comprising:
a spring module including:
at least one resilient member having a pair of wire parts extending side by side and a connecting part connecting the wire parts at ends of the wire parts; and
fastening members accommodating ends of the wire parts at one end of the resilient member and accommodating the connecting part at an opposite end of the resilient member,
wherein one of the fastening members is supported by a first housing of the housings and the other fastening member is supported by a second housing of the housings, and wherein a resilient force is provided in a direction along which the fastening members are positionable away from each other as the housings are slid with respect to each other.

16. The slide type portable terminal as claimed in claim 15, wherein at least a pair of resilient members are disposed such that one of the wire parts of one of the resilient members is disposed between the wire parts of the other resilient member.

17. The slide type portable terminal as claimed in claim 15, wherein three resilient members are disposed in parallel with each other such that connecting parts of a pair of first resilient members of the resilient members are coupled to a first fastening member of the fastening members and a connecting part of a second resilient member of the resilient members is coupled to a second fastening member of the fastening members.

18. The slide type portable terminal as claimed in claim 15, wherein each of the fastening members includes an accommodating part for accommodating one end of the resilient member and a fastening part integrally formed with the accommodating part.

19. The slide type portable terminal as claimed in claim 15, further comprising a guide member mounted to the first housing and slidably coupled to the second housing, wherein one of the fastening members is pivotally supported by the guide member on the first housing.

20. The slide type portable terminal as claimed in claim 15, further comprising a pivoting member formed in the second housing, wherein the other fastening member is coupled to and supported by the pivoting member.
